(19) United States
(12) Patent Application Publication
(10) Pub. No.: US 2018/0027191 A2
(43) Pub. Date: Jan. 25, 2018

(54) SYSTEM FOR CONTROLLING PIXEL ARRAY SENSOR WITH INDEPENDENTLY CONTROLLED SUB PIXELS

(71) Applicant: BRIGHTWAY VISION LTD., Haifa (IL)

(72) Inventor: Yoav GRAUER, Haifa (IL)

(73) Assignee: BRIGHTWAY VISION LTD., Haifa (IL)

(21) Appl. No.: 15/104,557

(22) PCT Filed: Dec. 17, 2014
(86) PCT No.: PCT/IL2014/051106

§ 371 Date: Jun. 15, 2016

(51) Int. Cl. H04N 5/33; H04N 13/02; H04N 9/04; H01L 27/146; H04N 5/225

(52) U.S. Cl. CPC H04N 5/332; H01L 27/14621; H04N 5/2256; H04N 9/045; H04N 13/0285; B60R 2300/307; B60R 2300/107

(57) ABSTRACT

A system for controlling a pixel array sensor with independently controlled sub pixels is provided herein. The system includes at least one image detector, comprising an array of photo-sensitive pixels, each photo-sensitive pixel comprising at least one first type photo-sensitive sub pixel and plurality of second type photo-sensitive sub pixels; and a processor configured to control the at least first type controlled photo-sensitive sub pixel and the plurality of second type second type photo-sensitive sub pixels according to a specified exposure scheme, wherein the processor is further configured to control the at least one first type sub pixel independently of the specified exposure scheme, wherein the processor is further configured to selectively combine data coming from the at least one first type sub pixel with data coming from at least one of the plurality of second type sub pixels.

### BACKGROUND

### 1. Technical Field

The disclosed technique relates to imaging systems, in general, and to method for object detection and classification system.

### 2. Discussion of Related Art

Traditional imaging sensors use a spectral pattern with various configurations such as Bayer pattern, “RGBW” (red, green, blue, white), “RCCC” (red, Clear, Clear, Clear) etc. These color or clear spectral filter pass a wide spectral region which masks the pure signal. Prior art has described also narrow spectral patterns on the imaging sensor pixels such Fabry-Perot filters. This approach may lack spectral information due to the narrow spectral band and may also lack immunity to backscattering for an active imaging approach.

Another prior art, U.S. Pat. No. 8,446,470, titled “Combined RGB and IR imaging sensor” describes an imaging system with plurality of sub-arrays having different sensing colors and infrared radiation. This proposed imaging system has inherent drawback in imaging wide dynamic range scenery of a single spectral radiation such as originating from a LED or a Laser where a saturated pixel may mask (due to signal leakage) a nearby non saturated pixel. Another drawback may occur in imaging scenery consisting a pulsed or modulated spectral radiation, such as originating from a LED or a Laser, where a pixel exposure is not synchronized or unsynchronized to this type of operation method.

Before describing the invention method, the following definitions are put forward.

The term “Visible” as used herein is a part of the electro-magnetic optical spectrum with wavelength between 400 to 700 nanometers.

The term “Infra-Red” (IR) as used herein is a part of the Infra-Red spectrum with wavelength between 700 nanometers to 1 mm.

The term “Near Infra-Red” (NIR) as used herein is a part of the Infra-Red spectrum with wavelength between 700 to 1400 nanometers.

The term “Short Wave Infra-Red” (SWIR) as used herein is a part of the Infra-Red spectrum with wavelength between 1400 to 3000 nanometers.

The term “Field Of View” (FOV) as used herein is the angular extent of a given scene, delineated by the angle of a three dimensional cone that is imaged onto an image sensor of a camera, the camera being the vertex of the three dimensional cone. The FOV of a camera at particular distances is determined by the focal length of the lens and the active image sensor dimensions.

The term “Field of Illumination” (FOI) as used herein is the angular extent of a given scene, delineated by the angle of a three dimensional cone that is illuminated from an illuminator (e.g. LED, LASER, flash lamp, ultrasound transducer, etc.), the illuminator being the vertex of the three dimensional cone. The FOI of an illuminator at particular distances is determined by the focal length of the lens and the illuminator illuminating surface dimensions.

The term “pixel” or “photo-sensing pixel” as used herein, is defined as a photo sensitive element used as part of an array of pixels in in an image detector device.

The term “sub pixel” or “photo-sensing sub pixel” as used herein, is defined as a photo sensitive element used as part of an array of sub pixels in a photo-sensing pixel. Thus, an image detector has an array of photo-sensing pixels and each photo-sensing pixel includes an array of photo-sensing sub pixels. Specifically, each photo-sensing sub pixel may be sensitive to a different range of wavelengths. Each one of the photo-sensing sub pixel are controlled in accordance with a second type exposure and/or readout scheme.

The term “second type exposure and/or readout scheme” of a photo-sensing sub pixel as used herein, is defined as a single exposure (i.e. light accumulation) of the photo sensitive element per a single signal read.

The term “first type sub pixel” or “first type photo-sensing sub pixel” as used herein, relates to a photo-sensing sub pixel which is controllable beyond the second type exposure scheme.

### BRIEF SUMMARY

In accordance with the disclosed technique, there is thus provided an imaging sensor (detector) or camera having an array of photo-sensitive pixels configuration that combines:
1. a mosaic spectral filter array photo-sensing sub pixels with at least two different spectrum sensitivity response;
2. a photo-sensing sub pixel exposure control mechanism for at least one type of the photo-sensing sub pixels;
3. a high anti-blooming ratio between adjacent sub pixels; and
4. a data transfer mechanism between at least two types of photo-sensing sub pixels to improve signal accumulation and noise reduction of imaging sensor (detector).

In one embodiment of the present invention, photo-sensitive pixel configuration as described hereinabove includes at least one sub pixel: “first type sub pixel” or “first type photo-sensing sub pixel” which relates to a photo-sensing sub pixel controllable beyond the second type exposure scheme.

In another embodiment of the present invention, exposure control mechanism (i.e. exposure scheme) for at least one first type sub pixel may provide a single exposure per sub pixel signal readout or multiple exposures per single sub pixel readout.

In another embodiment of the present invention, pixel signal readout may be a single channel or multiple readout channels.

In another embodiment of the present invention, at least one first type sub pixel may have a separate signal readout channel as to other sub pixels readout channel.

The imaging sensor (detector) or camera of the present invention is suitable for use in automotive camera products, such as for mono-vision based systems, providing driver assistance functionalities such as: adaptive headlamp control systems, lane departure warning (and/or lane keeping), traffic sign recognition, front collision warning, object detection (e.g. pedestrian, animal etc.), night vision and/or the like.

The imaging sensor (detector) or camera of the present invention is suitable for use in automotive camera products, such as for stereo-vision based systems, providing driver assistance functionalities such as: described hereinabove for mono-vision based systems, and 3D mapping information.

Therefore, the imaging sensor of the present invention can provide multi spectral imaging (for example both visible and IR imaging) capability with an adequate Signal to Noise (S/N) and/or adequate Signal to Background (S/B) for each photo-sensing sub pixel array in a single sensor frame, without halo (blooming) effect between adjacent sub pixels, and without external filters (such as spectral, polarization, intensity etc.). Such a sub pixel configuration of visible and IR pixels is applicable to various pixelated imaging array type sensing devices. The imaging sensor of the present invention is suitable for applications in maritime cameras, automotive cameras, security cameras, consumer digital cameras, mobile phone cameras, and industrial machine vision cameras, as well as other markets and/or applications.

These, additional, and/or other aspects and/or advantages of the present invention are: set forth in the detailed description which follows; possibly inferable from the detailed description; and/or learnable by practice of the present invention.

### BRIEF DESCRIPTION OF THE DRAWINGS

The present invention will be more readily understood from the detailed description of embodiments thereof made in conjunction with the accompanying drawings of which:

FIG. 1 is a schematic illustration of the operation of a mono vision system, constructed and operative in accordance with some embodiments of the present invention;

FIG. 2A-FIG. 2H are images taken with a SWIR active imaging system in accordance with some embodiments of the present invention;

FIGS. 3A-FIG. 3C are images taken with a NIR active imaging system in accordance with some embodiments of the present invention;

FIGS. 4A-4D are schematic diagrams of a pixel and sub pixel array in accordance with some embodiments of the present invention;

FIG. 5 is a schematic of a pixel and sub pixel array control in accordance with some embodiments of the present invention;

FIG. 6 is a schematic of a pixel and sub pixel array in accordance with some embodiments of the present invention;

FIG. 7 is a schematic of sensing structure with pixels in accordance with some embodiments of the present invention;

FIG. 8 is a schematic of an ADAS configuration in accordance with some embodiments of the present invention;

FIG. 9 is a schematic of sensing structure with a pixel array in accordance with some embodiments of the present invention; and

FIG. 10 is a schematic illustration of the operation of a stereo vision system, constructed and operative in accordance with some embodiments of the present invention.

### DETAILED DESCRIPTION

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

In accordance with the present invention, the disclosed technique provides methods and systems for accumulating a signal by a controllable spectral sensing element.

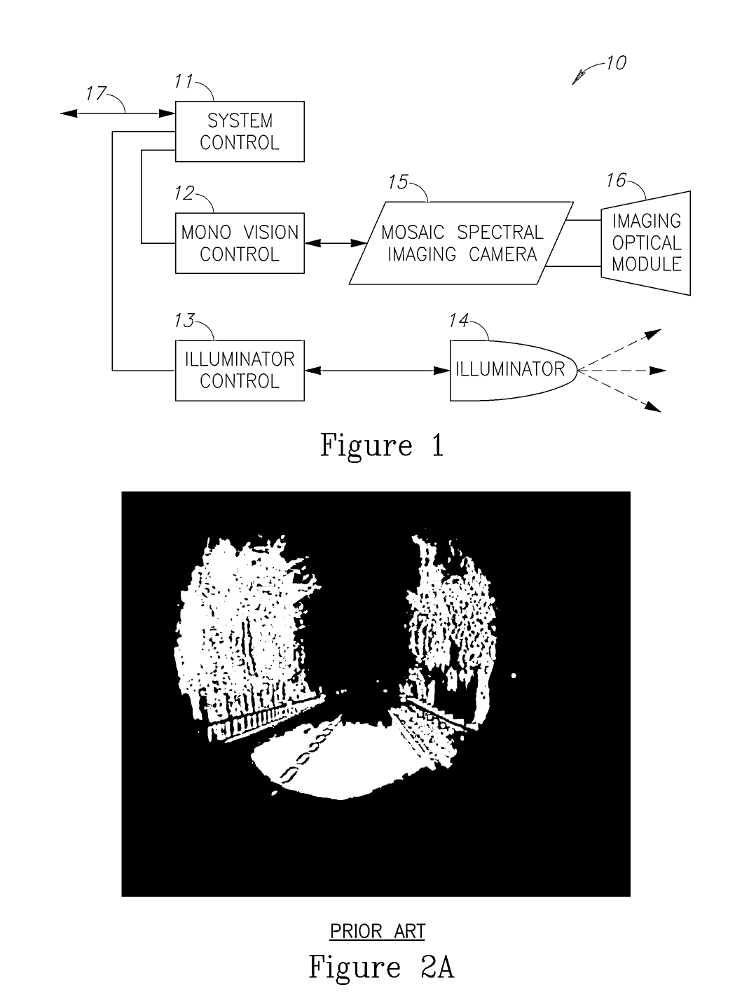

FIG. 1 is a schematic illustration of the operation of a mono vision system 10, constructed and operative in accordance with some embodiments of the present invention. System 10 which may include at least a single illuminator 14 in the non-visible spectrum (e.g. NIR or SWIR by a LED and/or laser source) in order to illuminate, for example, the environment. Furthermore, system 10 may also include at least a single mosaic spectral imaging camera 15. For automotive applications, imaging camera 15 may be located internally in the vehicle behind the mirror in the area cleaned by the windshield wipers forward facing. Mosaic spectral imaging camera 15 may be an intensified-CCD, intensified-CMOS (where the CCD/CMOS is coupled to an image intensifier), electron multiplying CCD, electron bombarded CMOS, hybrid FPA (CCD or CMOS where the camera has two main components; Read-Out Integrated Circuits and an imaging substrate), avalanche photo-diode FPA etc. Preferably, imaging camera 15 is a Complementary Metal Oxide Semiconductor (CMOS) Imager Sensor (CIS). System 10 may further include a system control 11 interfacing with user via output 17. Imaging optical module 16 is adapted to operate and detect electromagnetic wavelengths at least those provided by illuminator 14 and may also detect electromagnetic wavelengths of the visible spectrum and of the IR spectrum. Imaging optical module 16 is further adapted for focusing incoming light onto light sensitive area of mosaic spectral imaging camera 15. Imaging optical module 16 may be adapted for filtering certain wavelength spectrums, as may be performed by a band pass filter and/or adapted to filter various light polarizations. Imaging optical module 16 is adapted to operate and detect electromagnetic wavelengths similar to those detected by mosaic spectral imaging camera 15.

System 10 may include at least a single illuminator 14 in the non-visible spectrum (i.e. NIR, SWIR or NIR/SWIR spectrum) providing a Field Of Illumination (FOI) covering a certain part of the mosaic spectral imaging camera 15 FOV. Illuminator 14 may be a Continues Wave (CW) light source or a pulsed light source. Illuminator 14 may provide a polarized spectrum of light and/or a diffusive light.

System 10 further includes a system control 11 which may provide the synchronization of the mono vision control 12 to the illuminator control 13. System control 11 may further provide real-time image processing (computer vision) such as driver assistance features (e.g. pedestrian detection, lane departure warning, traffic sign recognition, etc.) in the case of an automotive usage. Mono vision control 12 manages the mosaic spectral imaging camera 15 such as: image acquisition (i.e. readout), de-mosaicking and imaging sensor exposure control/mechanism. Illuminator control 13 manages the illuminator 14 such as: ON/OFF, light source optical intensity level and pulse triggering for a pulsed light source configuration.

In accordance with some embodiment system 10 can be configured with gated imaging 15 capabilities for at least the sub pixels of a first type by synchronizing their gating with pulsed light present in the scene. The other type of sub pixels can remain unsynchronized with the pulsed light 14. The gated imaging feature presents advantages at daytime conditions, for nighttime conditions, light-modulated objects imaging (e.g. high repetition light flickering such as traffic sign etc.) and in poor visibility conditions. In addition, to enable target detection (i.e. any type of object such as car, motorcycle, pedestrian etc.) based on a selectively Depth-Of-Field (refereed hereinafter sometimes as “Slice”) in real time with an automatic alert mechanism conditions regarding accumulated targets. The gated imaging system may be handheld, mounted on a static and/or moving platform. Gated imaging system may even be used in underwater platforms, ground platforms or air platforms. The preferred platform for the gated imaging system herein is vehicular.

A gated imaging system is described in certain prior art such as patent: U.S. Pat. No. 7,733,464 B2, titled “vehicle mounted night vision imaging system and method”. Light source pulse (in free space) is defined as:

$${T}_{Laser} = 2 \times ( \frac{{R}_{0} - {R}_{min}}{c} ) ,$$

where the parameters defined in index below. Gated Camera ON time (in free space) is defined as:

$${T}_{II} = 2 \times ( \frac{{R}_{max} - {R}_{min}}{c} ) .$$

Gated Camera OFF time (in free space) is defined as:

$${T}_{Off} = \frac{2 \times {R}_{min}}{c} ,$$

where c is the speed of light, R₀, Rₘᵢₙ and Rₘₐₓ are specific ranges. The gated imaging is utilized to create a sensitivity as a function of range through time synchronization of T_{Laser}, T_{II} and T_{Off}.

Hereinafter a single “Gate” (i.e. at least a single light source pulse illumination followed by at least a single sensor exposure per a sensor readout) utilizes a specific T_{Lazer}, T_{H} and T_{Off} timing as defined above. Hereinafter “Gating” (i.e. at least a single sequences of; a single light source pulse illumination followed by a single sensor exposure and a single light source pulse illumination followed by a single sensor exposure ending the sequence a sensor readout) utilizes each sequence a specific T_{Laser}, T_{II} and T_{Off} timing as defined above. Hereinafter Depth-Of-Field (“Slice”) utilizes at least a single Gate or Gating providing a specific accumulated imagery of the viewed scene. Each DOF may have a certain DOF parameters that includes at least on the following; R₀, R_{Off} and Rₘₐₓ.

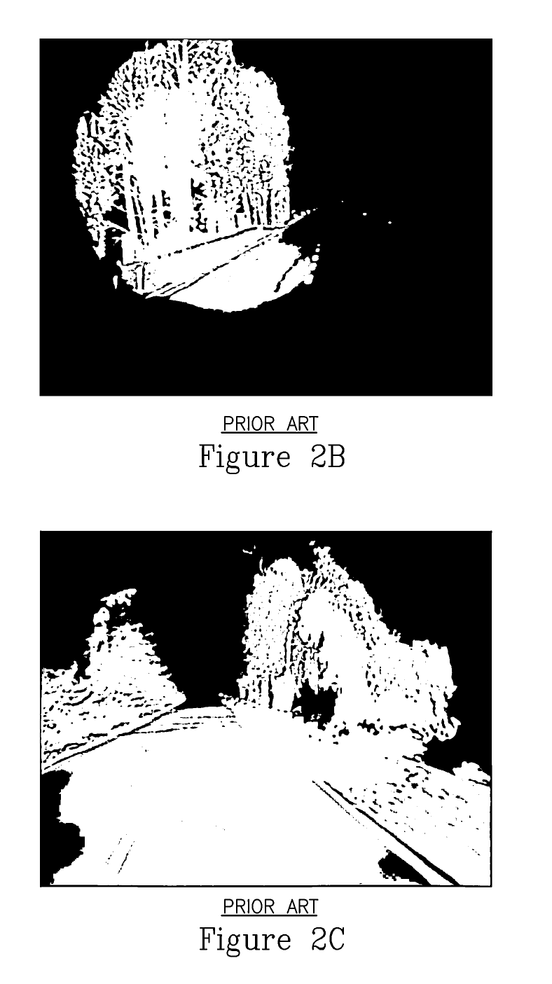

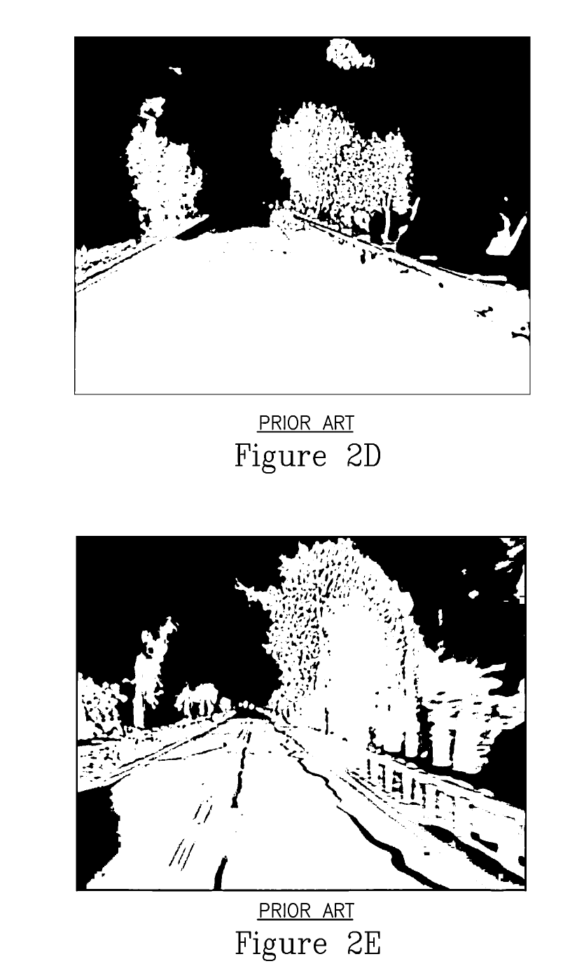

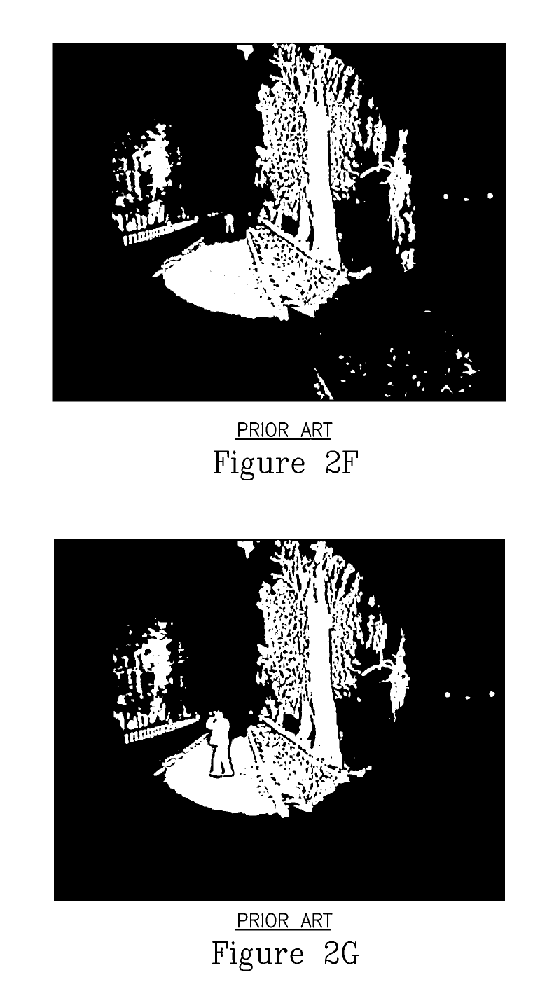

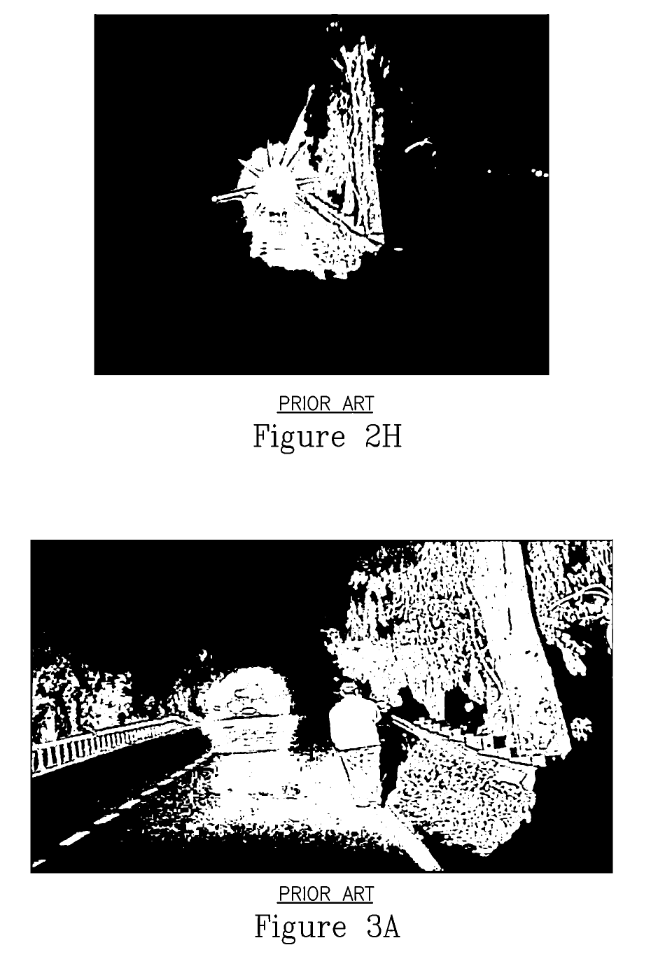

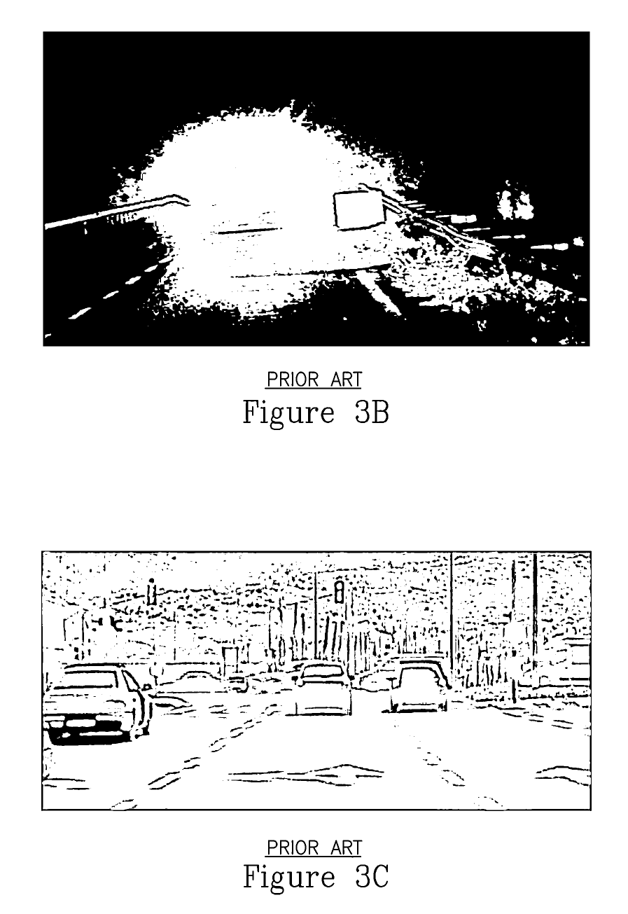

Prior describing embodiments of invention, FIG. 2A-FIG. 3C demonstrate some of the drawbacks of prior art. These images were taken with a single pattern filter imaging array having a single exposure control.

Reference is now made to FIG. 2A-FIG. 2H, where images were taken at nighttime with a system consisting a Continuous Wave (CW) SWIR laser illumination (i.e. 1.5 μm) and an imaging sensor sensitive to SWIR spectrum (i.e. 0.8-1.6 μm). This vehicular system imaging sensor FOV is wider than the SWIR FOI. Images scenery is typical for an interurban road. In FIG. 2A vehicular headlamps are not illuminating. The SWIR image is similar to a visible or MR reflected image where; the road marking are noticeable, safety fences on the road margins are noticeable and other objects are easily understood. In FIG. 2B vehicular headlamps are not illuminating. This SWIR image demonstrates the effect that close by objects (i.e. trees) have on active imaging (in this case a SWIR active imaging). The outcome is a saturated SWIR image. In FIG. 2C-FIG. 2D vehicular headlamps are illuminating (i.e. illuminating in the visible, NIR & SWIR spectrum). These SWIR images demonstrate the effect that close by objects (i.e. road) and the vehicle headlamp illumination have on active imaging (in this case a SWIR active imaging). The outcome is saturated SWIR images. In FIG. 2E vehicular headlamps are illuminating (i.e. illuminating in the visible, NIR & SWIR spectrum). This SWIR image demonstrates the effect that close by objects (i.e. road) and the vehicle headlamp illumination have on active imaging (in this case a SWIR active imaging). The outcome is saturated SWIR image but with noticeable road asphalt cracks that may be used to provide road surface data. In FIG. 2F-FIG. 2G vehicular headlamps are not illuminating. These SWIR images demonstrate the ability to observe a pedestrian crossing the road at about 50 m and about 120 m respectively with an active imaging (in this case a SWIR active imaging). In FIG. 2H vehicular headlamps are illuminating (i.e. illuminating in the visible, NIR & SWIR spectrum). This SWIR image demonstrates the effect that an oncoming vehicle with its headlights operating may saturate the imaging sensor.

Reference is now made to FIG. 3A-FIG. 3B, where images were taken at nighttime with a system consisting a CW NIR laser illumination (i.e. 0.8 μm) and an imaging sensor sensitive to MR spectrum (i.e. 0.81±0.05 μm due to a spectral filter in front the sensor) with a High Dynamic Range (HDR) of about 120 dB. This vehicular system imaging sensor FOV is wider than the NIR FOI. Images scenery is typical for an interurban road. In FIG. 3A vehicular headlamps are illuminating (i.e. illuminating in the visible & NIR spectrum). The NIR image is similar to a visible reflected image where; the road marking are noticeable, safety fences on the road margins are noticeable and other objects are easily understood. This NIR image demonstrates the ability to observe a pedestrian walking at about 40 m while an oncoming vehicle with its headlights operating. In this scenario a pedestrian walking further away (for example at a distance on the oncoming vehicle, about 100 m) will not be noticeable with this type of an active imaging (in this case a NIR active imaging) due to gain control, sensor sensitivity and dynamic range. In FIG. 3B vehicular headlamps are illuminating (i.e. illuminating in the visible & NIR spectrum). This NIR image demonstrates the effect that an oncoming vehicle, with its high beam headlights operating, may saturate the imaging sensor.

Reference is now made to FIG. 3C, where the image was taken at daytime with a system consisting an imaging sensor sensitive to MR spectrum (i.e. 0.81±0.05 μm due to a spectral filter in front the sensor). This image scenery is typical for urban scenario. The NIR image is similar to a visible reflected image where; the road marking are noticeable, traffic light signals are noticeable and other objects are easily understood. This NIR image lacks wide spectral data such as; red spectrum (i.e. stop sign on both sides of the intersection or vehicle tale lights) or the visible spectrum for some of lane marking traffic signals using LEDs. This NIR image demonstrates the effect that spectral data is required from the imaging sensor in order to achieve higher understanding of the viewed scenery.

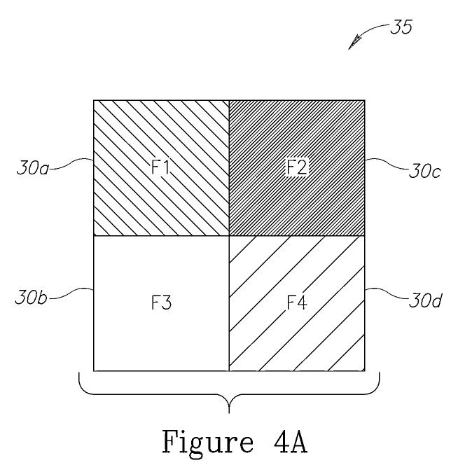

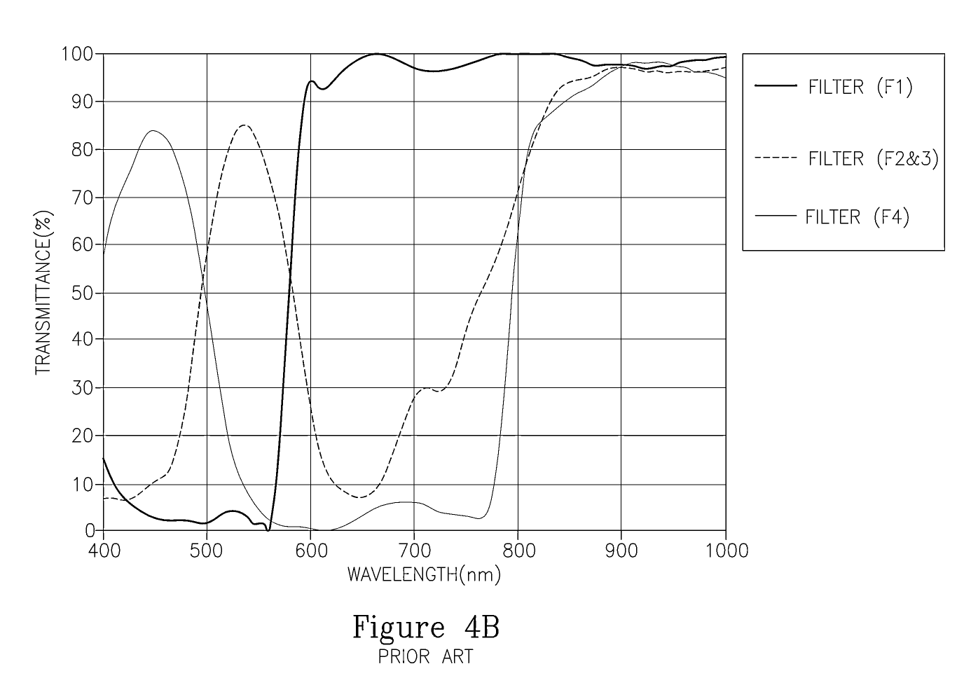

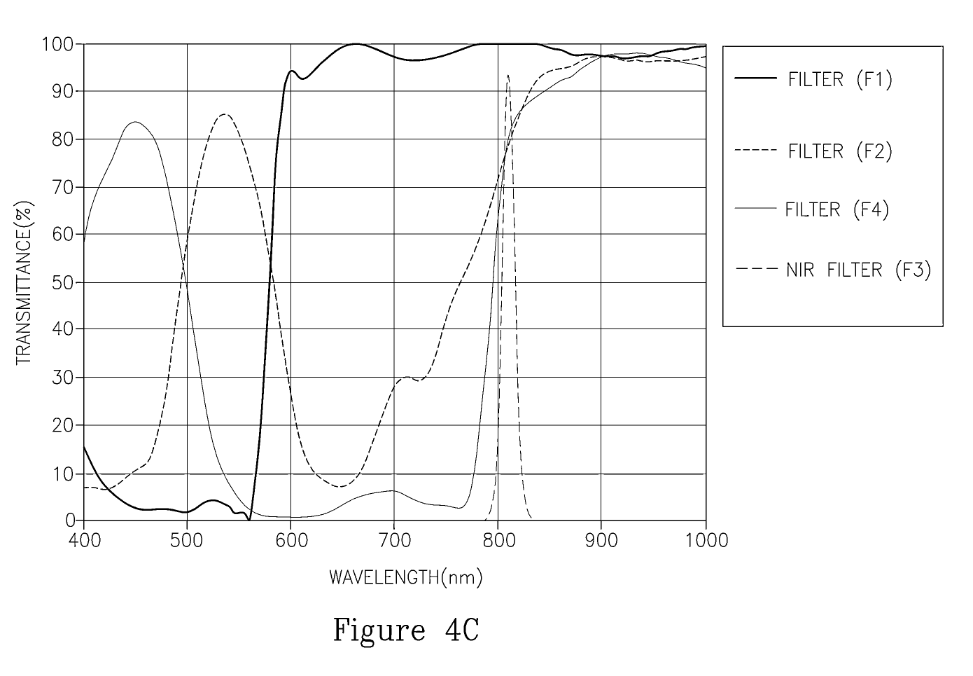

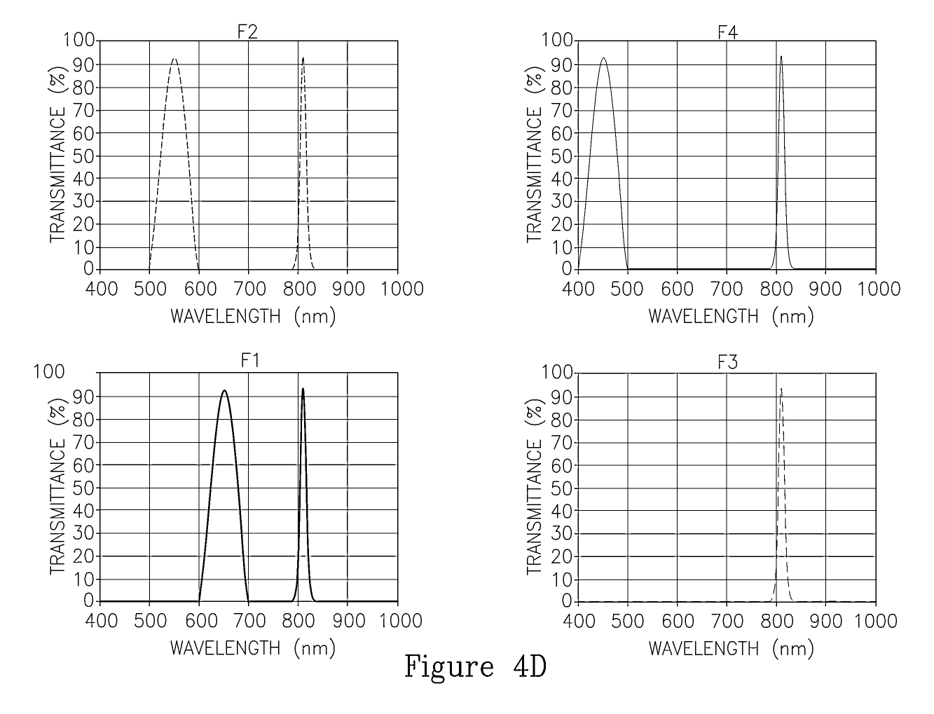

FIG. 4A illustrates a mosaic spectral imaging sensor pixel 35 (two by two sub pixel that is repeated over the pixelated array of imaging sensor 15) constructed and operative in accordance with some embodiments of the present invention. In such a pixelated array, the imaging sensor (detector) 15 includes individual optical filters that may transmit different spectrum: F1 spectrum 30a, F2 spectrum 30c, F3 spectrum 30b and F4 spectrum 30d. Each transmitted spectrum (F1, F2, F2 and F3) may include at least one the following types of spectral filtration;
1. Long Pass Filter (LPF).
2. Short Pass Filter (SPF).
3. Band Pass Filter (BPF) with a Center Wavelength (CWL) transmission, Full Width Half Maximum (FWHM) and peak transmission.
4. Polarization.
5. Optical density (intensity).
   For example, this representation can define standard pixelated filters as indicated in the following table.

| | Example 1 | Example 2 |
|---|---|---|
| | (Standard Bayer filter) | (Standard RCCC filter) |
| Sub pixel F1 | (R), Red information, | (R), Red information, |
| | high transmission | high transmission |
| | in the red spectrum. | in the red spectrum. |
| Sub pixel F2 | (G), Green information, | (C), Clear information, |
| | high transmission | no spectral filtration |
| | in the green spectrum. | introduced on the pixel. |
| Sub pixel F3 | (G), Green information, | (C), Clear information, |
| | high transmission | no spectral filtration |
| | in the green spectrum. | introduced on the pixel. |
| Sub pixel F4 | (B), Blue information, | (C), Clear information, |
| | high transmission | no spectral filtration |
| | in the blue spectrum. | introduced on the pixel. |

For example this representation can define pixelated filters as indicated in the following table.

| | Example 3 | Example 4 |
|---|---|---|
| | (R, C, C, NIR) | (R, C, NIR, SWIR) |
| Sub pixel F1 | (R), Red information, | (R), Red information, |
| | high transmission | high transmission |
| | in the red spectrum. | in the red spectrum. |
| Sub pixel F2 | (C), Clear information, | (C), Clear information, |
| | no spectral filtration | no spectral filtration |
| | introduced on the pixel. | introduced on the pixel. |
| Sub pixel F3 | (C), Clear information, | (NIR), NIR information: |
| | no spectral filtration | CWL transmission: 810 nm |
| | introduced on the pixel. | FWHM: 20 nm |
| | | Off band rejection <5% |
| Sub pixel F4 | (NIR), NIR information | (SWIR), SWIR information |
| | with a BPF: | with a LPF: |
| | CWL transmission: 850 nm | Transmission wavelength: |
| | FWHM: 15 nm | 1400-1600 nm |
| | Off band rejection <1% | Cut-on wavelength (50% |
| | | transmission): 1350 nm |

A signal output, Signal(e) expressed in electrons, of prior art imaging 2D sensing element (i.e. sub pixel) without an internal gain and neglecting noise can be expressed by:

$$Signal ( e ) = {S}_{λ} \cdot \frac{P ( λ )}{Area} \cdot {d}_{width} \cdot {d}_{length} \cdot {t}_{exposure}$$

S_{λ} is the sensing element response (responsivity) to a specific wavelength (i.e. S_{λ}=QE(λ). FF(λ), QE(λ) is the quantum efficiency and FF(λ) is the sub pixel fill factor),

$$\frac{P ( λ )}{Area}$$

is the optical power density at a specific wavelength, d_{width}·d_{length} is the photo-sensing active area of the sub pixel (e.g. pin diode, buried pin diode etc.) and tₑₓₚₒₛᵤᵣₑ is the sub pixel exposure duration to the optical power density. Thus, taking into account that a Color Filter Array (CFA) and/or any type of spectral pattern (as illustrated in FIG. 4A) is introduced on the imaging sensor array may result in an uneven signal (Signal(e)) from each sub pixel type and/or “spill” of signal (causing blooming/saturation) between the different spectral pattern sub pixels.

FIG. 4B illustrates a mosaic spectral imaging sensor pixel 35 (two by two sub pixel that is repeated over the pixelated array of imaging sensor 15) constructed and operative in accordance with some embodiments of the present invention. The pattern is a Standard Bayer filter array. As one can see, the filters spectral responses (transmission curves) are overlapping and “open” (i.e. high transmission) in the Visible/NIR. This spectral configuration may have degraded performance in day-time. The reason is sun irradiance which has more photons in NIR versus the visible spectrum resulting in lack of visible spectrum discrimination. A common solution is by introducing a constant or movable spectral filter (e.g. LFP, BPF, polarizer etc.) which reduces/blocks the NIR spectrum.

FIG. 4C illustrates a mosaic spectral imaging sensor pixel 35 (two by two sub pixel that is repeated over the pixelated array of imaging sensor 15) constructed and operative in accordance with some embodiments of the present invention. The pattern is a similar to a Bayer filter array where one of the pixels (F3) is processed/fabricated with a narrow NIR filter (i.e. FWHM of 10 nm). This spectral configuration provides the ability of visible & NIR spectrum in a single image frame in two operating modes; in passive mode (i.e. without system illumination) and active mode (i.e. with system NIR system illumination). The illumination may be pulsed (synchronized) or CW. This configuration may lack the same visible spectrum discrimination as describe hereinabove. At scenarios where an active mode is operated some of the pixels (F1, F2 & F4) may not detect the NIR illumination due to signal clutter. Signal clutter may origin in the visible spectrum or the NIR spectrum where these pixels have wide spectral filters (i.e. transmittance is high in a wide spectrum). This spectral configuration may lack to provide a full pixel array NIR resolution at night-time and day-time.

FIG. 4D illustrates a mosaic spectral imaging sensor pixel 35 (two by two sub pixel that is repeated over the pixelated array of imaging sensor 15) constructed and operative in accordance with some embodiments of the present invention. The pattern is a different from a Bayer filter array where some of the pixels are processed/fabricated with a wide spectral filter (i.e. FWHM of 100 nm with an optical density of at least two outside this spectral band) and all of the pixels are processed/fabricated with a narrow spectral filter (i.e. FWHM of 10 nm with an optical density of at least two outside this spectral band). This spectral configuration provides the ability of visible & NIR spectrum in a single image frame in two operating modes; in passive mode (i.e. without system illumination) and active mode (i.e. with system NIR system illumination). The illumination may be pulsed (synchronized) or CW. The peak transmission of each response curve may be different. This configuration is ideal for providing visible spectrum information (which is not overlapping between the pixels/filters), NIR information (which is overlapping between the pixels/filters) to provide a full pixel array NIR resolution at night-time and day-time (i.e. the pixels transmission is overlapping in the NIR spectral band).

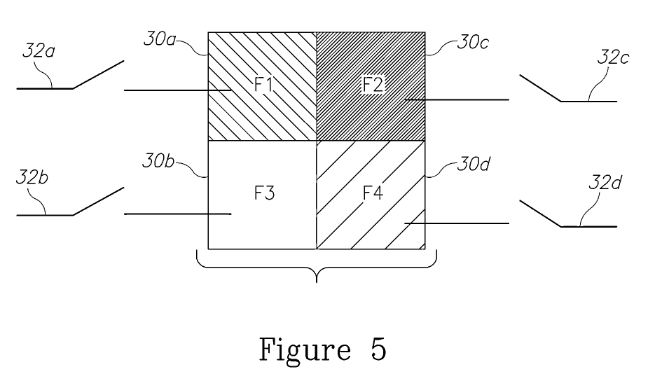

FIG. 5 illustrates a mosaic spectral imaging sensor (detector) pixel 35 (two by two sub pixel array that is repeated over the pixelated array of imaging sensor 15) constructed and operative in accordance with some embodiments of the present invention. Each sub pixel pattern may have an exposure control capability (32a for 30a, 32b for 30b, 32c for 30c and 32d for 30d) to enable an uniform and controllable signal accumulation (Signal(e)) for sensor pixel 35.

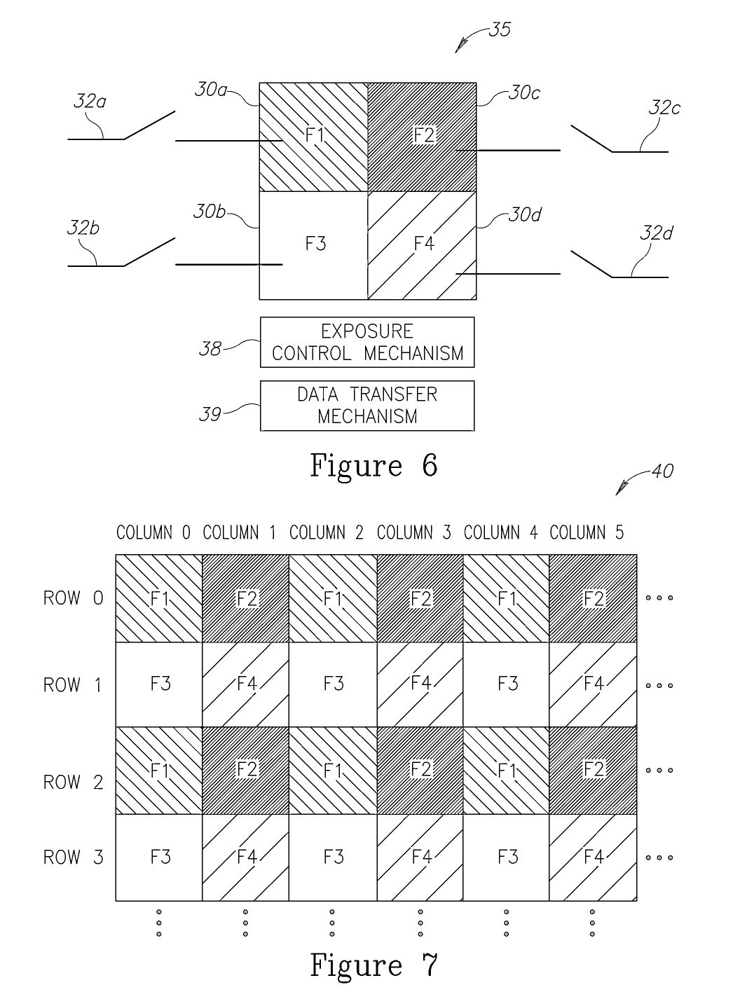

FIG. 6 illustrates a mosaic spectral imaging sensor (detector) pixel 35 (two by two sub pixel array that is repeated over the pixelated array of imaging sensor 15) constructed and operative in accordance with some embodiments of the present invention. At least a single sub pixel pattern (i.e. first type sub pixel) may have an exposure control capability (FIG. 6 illustrate four first type sub pixel; 32a for 30a, 32b for 30b, 32c for 30c and 32d for 30d) to enable a uniform and controllable signal accumulation (Signal(e)) for sensor pixel 35. An exposure control mechanism 38 may be integrated in the imaging sensor or located externally of the imaging sensor. Each sub pixel pattern exposure control mechanism (e.g. exposure scheme) may operate separately, may operate in different timing, may operate in single exposure duration per single sub pixel signal readout and may operate with multiple exposures per single sub pixel signal readout. Exposure control mechanism 38 (controlling 32a, 32b, 32c and 32d) may be a gate-able switch, a controllable transistor or any other method of exposing and accumulating a signal in the sub pixel. Each sub pixel pattern exposure control mechanism may be synchronized or unsynchronized to external light source such as illustrated in FIG. 1 (Illuminator 14). Exposure control mechanism 38 provides multi-functionality in a single imaging sensor (detector). Furthermore, exposure control mechanism 38 provides the sub pixels to operate in a second type exposure and/or readout scheme or to provide for at least a single first type sub pixel to operate with a different exposure scheme. In addition, an anti-blooming mechanism is integrated in each type of sub pixel. Thus, a saturated sub pixel will not affect adjacent sub pixels (i.e. saturated sub pixel accumulated signal will not “spill” to nearby sub pixels). An anti-blooming ratio of above 1,000 may be sufficient. The mosaic spectral imaging sensor pixel 35 may include internally or externally a data transfer mechanism 39. Data transfer mechanism 39 probes each type of photo-sensing sub pixel accumulated signal to improve signal accumulation in other types of photo-sensing sub pixels. This method may be executed in the same imaging sensor 15 frame and/or in the following image sensor 15 frames.

FIG. 7 illustrates a section of a mosaic spectral imaging sensor pixels 40 (two by two sub-array pixel 35 that is repeated over the pixelated array of imaging sensor 15) constructed and operative in accordance with some embodiments of the present invention. A sub-array exposure control mechanism 38 and data transfer mechanism 39 (as described hereinabove) are not illustrated for reasons of simplicity. Imaging sensor pixels 40 resolution format may be flexible (e.g. VGA, SXGA, HD, 2 k by 2 k etc.). Sub-Array 35 may be distributed in a unified pattern spread or a random pattern spread over spectral imaging sensor pixels 40. Mosaic spectral imaging sensor pattern 40 readout process may be executed by rows, by columns and/or by reading-out similar sub pixels type. For example all first type sub pixels (for example F1) shall be readout by a separate readout channel versus other sub pixels (F2, F3 and F4) that are readout by a different readout channel. This readout capability provides another layer of flexibility in the imaging sensor 15.

In another embodiment, fusion frames of mosaic spectral imaging sensor pixels 40 (two by two sub pixel array 35 that is repeated over the pixelated array of imaging sensor 15) provides yet another layer of information. A fused frame may provide data such as: moving objects types in the imaging sensor FOV, trajectory of moving objects in the imaging sensor FOV, scenery conditions (for example, ambient light level) or any other spectral, time variance data of the viewed scenery.

In another embodiment, in case of a moving platform (i.e. imaging sensor pixels 40 is movable) fused frames may provide yet another layer of information. A fused frame may provide full resolution image of the viewed FOV with at least a single spectral photo-sensing sub pixel.

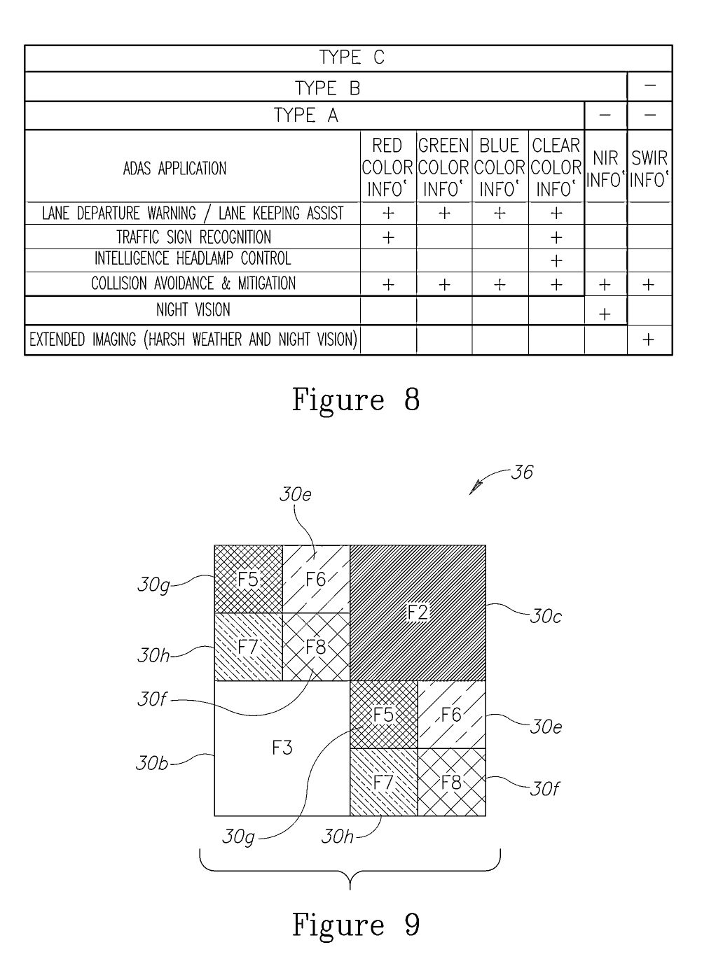

Advance Driver Assistance Systems (ADAS) imaging based applications may require spectral information (info′) as presented in FIG. 8. Collision avoidance and mitigation includes all types of objects such as; pedestrians, cyclists, vehicles and/or any other type of an object captured by the imaging system. Type A-Type C may define a specific ADAS configuration. System 10 may provide at least the above ADAS applications where mosaic spectral imaging sensor pixels 40 are incorporated in mosaic spectral imaging camera 15. For example, Type A and Type B may be based on a CMOS imager sensor where Type C may be based on an InGaAs imager sensor. For example, pixel 35 Type A and pixel 35 type B may be as follows.

| | Pixel 35 Type A | Pixel 35 Type B |
|---|---|---|
| Sub pixel F1 | (R), Red information, | (R), Red information, |
| | high transmission | high transmission |
| | in the red spectrum. | in the red spectrum. |
| Sub pixel F2 | (G), Green information, | (C), Clear information, |
| | high transmission | no spectral filtration |
| | in the green spectrum. | introduced on the pixel. |
| Sub pixel F3 | (B), Blue information, | (C), Clear information, |
| | high transmission | no spectral filtration |
| | in the blue spectrum. | introduced on the pixel. |
| Sub pixel F4 | (C), Clear information, | (NIR), NIR information |
| | no spectral filtration | with a BPF: |
| | introduced on the pixel. | CWL transmission: 808 nm |
| | | FWHM: 15 nm |
| | | Off band rejection <1% |

In addition each type (Type A and/or Type B) may have different exposure control mechanism (and anti-blooming ratio as defined hereinabove.

For another example, sub-Array 35 Type C may be at least on the options as follows.

| | Type C (option1) | Type B (option2) |
|---|---|---|
| F1 | (R), Red information, | (R), Red information, |
| | high transmission | high transmission |
| | in the red spectrum. | in the red spectrum. |
| F2 | (C), Clear information, | (C), Clear information, |
| | no spectral filtration | no spectral filtration |
| | introduced on the pixel. | introduced on the pixel. |
| F3 | (NIR), NIR information: | (NIR), NIR information: |
| | CWL transmission: 810 nm | CWL transmission: 810 nm |
| | FWHM: 20 nm | FWHM: 20 nm |
| | Off band rejection <5% | Off band rejection <5% |
| F4 | (SWIR), SWIR information | (SWIR), SWIR information |
| | with a LPF: | with a BPF: |
| | Transmission wavelength: | CWL transmission: 1540 nm |
| | 1300-1600 nm | FWHM: 15 nm |
| | Cut-on wavelength (50% | Off band rejection <1% |
| | transmission): 1250 nm | |

In addition each type option (Type C option 1 and/or option 2) may have different exposure control mechanism (i.e. exposure scheme) and anti-blooming ratio as defined hereinabove.

In another embodiment, system 10 may provide at least the above ADAS applications in addition to predication of areas of interest where a mosaic spectral imaging sensor pixels 40 is incorporated in mosaic spectral imaging camera 15. Predicated areas of interest may include: objects in the viewed scenery (e.g. road signs, vehicles, traffic lights, curvature of the road etc.) and similar system approaching system 10.

FIG. 9 illustrates a mosaic spectral imaging sensor pixel 36 (sub-array that is repeated over the pixelated array of imaging sensor 15) constructed and operative in accordance with some embodiments of the present invention. Mosaic spectral imaging sensor pixel 36 is similar to mosaic spectral imaging sensor pixel 35 in almost every aspect expect: sub pixel dimensions and the number of sub pixels per area. In such a pixelated array, the imaging sensor 15 includes individual optical filters that transmit; F2 spectrum 30c, F3 spectrum 30b, F5 spectrum 30g, F6 spectrum 30e, F7 spectrum 30h and F8 spectrum 30f. Each transmitted spectrum (F2 to F8) may include at least one the following types of spectral filtration;
1. Long Pass Filter (LPF).
2. Short Pass Filter (SPF).
3. Band Pass Filter (BPF) with a Center Wavelength (CWL) transmission, Full Width Half Maximum (FWHM) and peak transmission.
4. Polarization.
5. Optical density (intensity).
   A sub-array exposure control mechanism 38 and data transfer mechanism 39 (as described hereinabove) are not illustrated for reasons of simplicity. As the signal output, Signal(e) is directly related the photo-sensing active area of the sub pixel (d_{width}·d_{length}) this proposed embodiment provides another layer of flexibility in sensing a wide dynamic range scene that may have also a wide spectrum distribution. Taking into account also S_{λ} (sensing element response, responsivity) with this proposed embodiment can provide a unified imaging sensor 15 output from the entire array.

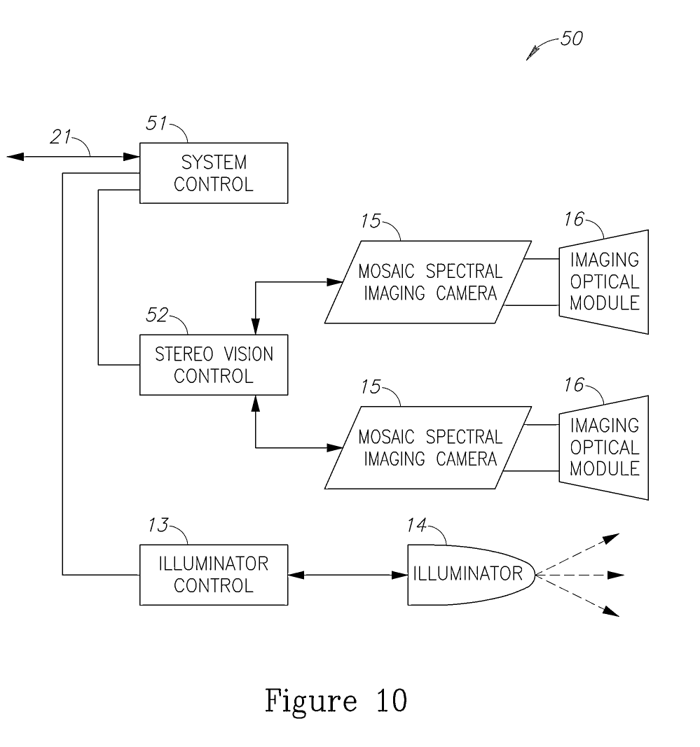

FIG. 10 illustrates a stereo vision system 50 constructed and operative in accordance with some embodiments of the present invention. Stereo vision system 50 is similar to mono vision system 10 in almost every aspect expect: an additional imaging channel and an addition processing layer is added which provides also 3D mapping information in day-timing conditions, night-time conditions and any other light conditions. Stereo vision control 52 provides functionality as mono vision control 12 and also synchronizes each mosaic spectral imaging camera 15. Stereo vision system control 51 provides functionality as mono vision system control 11 and also includes all algorithms for 3D mapping. Stereo vision interfacing with user via output 21 provides functionality as mono vision system interfacing with user via output 17 and may also include 3D mapping information.

While the invention has been described with respect to a limited number of embodiments, these should not be construed as limitations on the scope of the invention, but rather as exemplifications of some of the preferred embodiments. Other possible variations, modifications, and applications are also within the scope of the invention.

1. A system comprising:
at least one image detector, comprising an array of photo-sensitive pixels, each photo-sensitive pixel comprising at least one first type photo-sensitive sub pixel and at least one second type photo-sensitive sub pixel; and
a processor configured to control the at least one first type controlled photo-sensitive sub pixel and the at least one second type photo-sensitive sub pixels according to a specified exposure scheme,
wherein an exposure of at least one of the first type photo-sensitive sub pixel is synchronized with pulsed light present in the scene, to achieve gated images of the scene,
wherein the processor is further configured to control the at least one first type sub pixel independently of the specified exposure scheme, and
wherein the processor is further configured to selectively combine data coming from the at least one first type sub pixel with data coming from the at least one second type sub pixel.

2. The system according to claim 1, wherein the processor is further configured to control at least one of: exposure, and readout, of the at least one first type sub pixel, based on data coming from the at least one second type sub pixel.

3. The system according to claim 1, wherein the photo sensitive sub pixels have an anti-blooming capability so that a saturated sub pixel does not affect adjacent sub pixels.

4. The system according to claim 3, wherein the anti-blooming capability exhibit a ratio that is greater than 1:1000.

5. The system according to claim 1, wherein the system is mounted on a moving platform.

6. The system according to claim 1, wherein the at least one first type photo-sensitive sub pixel is infra-red (IR) sensitive.

7. The system according to claim 6, wherein the at least one first type photo-sensitive sub pixel has a full width half maximum transmission of up to five percent of the center wavelength.

8. The system according to claim 7, wherein the at least one first type photo-sensitive sub pixel has an off band rejection of less than ten percent.

9. The system according to claim 1, wherein the at least one first type photo-sensitive sub pixel is sensitive to visible spectrum.

10. The system according to claim 9, wherein the at least one first type photo-sensitive sub pixel has a full width half maximum transmission of up to ten percent of the center wavelength.

11. The system according to claim 10, wherein the at least one first type photo-sensitive sub pixel has an off band rejection of less than ten percent.

12. The system according to claim 1, wherein the at least one first type photo-sensitive sub pixel has a larger area than the at least one second type photo-sensitive sub pixel.

13. The system according to claim 1, wherein the at least one first type photo-sensitive sub pixel has a smaller area than the area of the at least one second type photo-sensitive sub pixel.

14. The system according to claim 1, wherein the at least one first type photo-sensitive sub pixel comprises readout channel which is separate from the readout channel of the at least one second type photo-sensitive sub pixel.

15. The system according to claim 1, wherein the at least one first type photo-sensitive sub pixel is coupled to an amplifier configured to amplify a signal coming from the at least one first type photo-sensitive sub pixel independently of the signals coming from the at least one second type photo-sensitive sub pixel.

16. (canceled)

17. The system according to claim 1, wherein the at least one first type photo-sensitive sub pixel exposure scheme is synchronized with an external light source pulsing scheme.

18. The system according to claim 1, wherein the at least one first type photo-sensitive sub pixel exposure scheme is synchronized with an external light source modulation scheme.

19. The system according to claim 1, further comprising an external light source and wherein the at least the first type sub pixel is coupled to a filter having a spectral range similar to a spectral range of the external light source.

20. The system according to claim 1 wherein the data selectively combined by the processor includes data captured at different exposure times.

21. The system according to claim 1, wherein the selectively combined data coming from the at least one first type sub pixel with data coming from at least one of the plurality of second type sub pixels is usable for Advance Driver Assistance Systems (ADAS) functions.

22. The system according to claim 1, further comprising a pulsed light source configured to generate the pulsed light present in the scene.

23. The system according to claim 1, wherein the processor is configured to detect parameters of the pulsed light for synchronizing the at least one of the first type photo-sensitive sub pixel, wherein the pulsed light present in the scene is generated independently of the system.

24. The system according to claim 1, wherein the photo-sensitive pixels are infra-red (IR) sensitive and wherein at least one of the first type photo-sensitive sub pixel is further sensitive to a visible light spectrum.

25. The system according to claim 24, wherein the selective combining data by the processor is usable for providing an infra-red (IR) image of the array of photo-sensitive pixels.

26. The system according to claim 24, wherein the selective combining data by the processor is usable for providing an infra-red (IR) and visible spectrum image of the array of photo-sensitive pixels.
